(19) United States
(12) Patent Application Publication
(10) Pub. No.: US 2026/0063739 A1
(43) Pub. Date: Mar. 5, 2026

(54) RADIO FREQUENCY COIL AND RESONANCE ASSEMBLY FOR MAGNETIC RESONANCE IMAGING SYSTEM

(71) Applicant: GE Precision Healthcare LLC, Waukesha, WI (US)

(72) Inventor: Tingting Song, Beijing (CN)

(21) Appl. No.: 19/315,455

(22) Filed: Aug. 29, 2025

(30) Foreign Application Priority Data
Aug. 30, 2024 (CN) 202411215074.7

(51) Int. Cl. G01R 33/34; G01R 33/36

(52) U.S. Cl. CPC G01R 33/34076; G01R 33/34023; G01R 33/3628

(57) ABSTRACT

A radio frequency coil and a resonance assembly for a magnetic resonance imaging system are provided. The radio frequency coil has a first end and a second end in an axial direction, the radio frequency coil including: a first conductor portion at the first end, the first conductor portion including a first arc-shaped conductor and a second arc-shaped conductor opposed in a radial direction; and a second conductor portion at the second end; the second conductor portion including a third arc-shaped conductor and a fourth arc-shaped conductor opposed in the radial direction; wherein the first arc-shaped conductor and the third arc-shaped conductor are opposed in the axial direction, and the second arc-shaped conductor and the fourth arc-shaped conductor are opposed in the axial direction, and there are no rung conductors directly connected between the first conductor portion and the second conductor portion.

### CROSS REFERENCE TO RELATED APPLICATIONS

The present application claims priority and benefit of Chinese Patent Application No. 202411215074.7 filed on Aug. 30, 2024, which is incorporated herein by reference in its entirety.

### TECHNICAL FIELD

The present disclosure relates to the field of medical imaging, and more specifically to a radio frequency coil for a magnetic resonance imaging system and a resonance assembly for a magnetic resonance imaging system.

### BACKGROUND

Magnetic resonance imaging (MRI), as a medical imaging mode, can generate images of a patient's interior without X-ray radiation or other types of ionizing radiation. An MRI system is a medical imaging device that utilizes superconducting magnets to generate a strong, uniform static magnetic field within a designated area (e.g., within a channel shaped to receive a patient). When the patient's body (or a portion of the patient's body) is positioned within the magnetic field, nuclear spins associated with hydrogen nuclei forming water within tissues of the patient become polarized. Magnetic moments associated with these spins are arranged in a magnetic field direction and induce small net tissue magnetization in the magnetic field direction. The MRI system additionally includes a magnetic gradient coil that generates spatially varying magnetic fields having a magnitude smaller than the magnitude of the uniform magnetic field generated by the superconducting magnet. The spatially varying magnetic fields are configured so that they are orthogonal to each other, so as to perform spatial encoding on different locations in a patient by creating characteristic resonance frequencies of hydrogen nuclei at the locations. A radio frequency (RF) coil assembly is then used to generate pulses having RF energy at or near resonance frequencies of the hydrogen nuclei. The pulses having RF energy are absorbed by the hydrogen nuclei, adding energy to a nuclear spin system and conditioning the hydrogen nuclei from a rest state to an excited state. When the hydrogen nuclei relax from the excited state back to the rest state, they release absorbed energy in the form of an RF signal. The signal is detected by the MRI system and transformed into an image by a computer using a known reconstruction method.

Birdcage coils have been used as a type of radio frequency coil. Birdcage coils have a complex structure, which leads to an increase in the overall costs of the MRI system.

### SUMMARY

The objective of the present disclosure is intended to overcome the above-mentioned and/or other problems in the prior art. According to the present invention, a radio frequency coil and a resonance assembly for a magnetic resonance imaging system are provided, which have simple structures and are convenient to mount, facilitating the design and maintenance thereof.

According to a first aspect of the present disclosure, provided is a radio frequency coil for a magnetic resonance imaging device, the radio frequency coil having a first end and a second end in an axial direction, and the radio frequency coil may comprise: a first conductor portion at the first end, the first conductor portion comprising a first arc-shaped conductor and a second arc-shaped conductor opposed in a radial direction; and a second conductor portion at the second end; the second conductor portion comprising a third arc-shaped conductor and a fourth arc-shaped conductor opposed in the radial direction; wherein the first arc-shaped conductor and the third arc-shaped conductor are opposed in the axial direction, the second arc-shaped conductor and the fourth arc-shaped conductor are opposed in the axial direction, and there are no rung conductors directly connected between the first conductor portion and the second conductor portion.

In an embodiment, the first arc-shaped conductor, the second arc-shaped conductor, the third arc-shaped conductor, and the fourth arc-shaped conductor may be configured to operate simultaneously in a first excited state and a second excited state, wherein the first excited state and second excited state differ in phase by 90 degrees, in the first excited state, currents at both ends of each arc-shaped conductor are less than a current at the center, and in the second excited state, the current at the center of each arc-shaped conductor is less than the currents at both ends.

In an embodiment, both ends of each of the first arc-shaped conductor, the second arc-shaped conductor, the third arc-shaped conductor, and the fourth arc-shaped conductor may be connected to different excitation sources, and the different excitation sources are configured to apply currents in opposite directions to both ends of each of the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

In an embodiment, each of the first arc-shaped conductor, the second arc-shaped conductor, the third arc-shaped conductor, and the fourth arc-shaped conductor may be configured in a resonant state, only one end of each of the first arc-shaped conductor, the second arc-shaped conductor, the third arc-shaped conductor, and the fourth arc-shaped conductor is connected to a respective excitation source, and the excitation source is configured to apply a current to the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

In an embodiment, a middle point of each of the first arc-shaped conductor, the second arc-shaped conductor, the third arc-shaped conductor, and the fourth arc-shaped conductor may be connected to a respective balun, and the baluns are configured to apply currents to the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

In an embodiment, both ends of each of the first arc-shaped conductor, the second arc-shaped conductor, the third arc-shaped conductor, and the fourth arc-shaped conductor may be connected to different excitation sources, and the different excitation sources are configured to apply currents in a same direction to both ends of each of the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the second excited state.

In an embodiment, the first conductor portion may further comprise a fifth arc-shaped conductor and a sixth arc-shaped conductor opposed in the radial direction, the fifth arc-shaped conductor and the sixth arc-shaped conductor are respectively disposed on two sides between the first arc-shaped conductor and the second arc-shaped conductor, the first arc-shaped conductor and the second arc-shaped conductor form a circular ring shape together with the fifth arc-shaped conductor and the sixth arc-shaped conductor, the second conductor portion further comprises a seventh arc-shaped conductor and an eighth arc-shaped conductor opposed in the radial direction, the seventh arc-shaped conductor and the eighth arc-shaped conductor are respectively disposed on two sides between the third arc-shaped conductor and the fourth arc-shaped conductor, and the third arc-shaped conductor and the fourth arc-shaped conductor form a circular ring shape together with the seventh arc-shaped conductor and the eighth arc-shaped conductor.

In an embodiment, the first to eighth arc-shaped conductors may be configured to operate in a first excited state, wherein in the first excited state, currents at both ends of each arc-shaped conductor are less than a current at the center.

In an embodiment, both ends of each of the first to eighth arc-shaped conductors may be connected to different excitation sources, and the different excitation sources are configured to apply currents in opposite directions to both ends of each of the first to eighth arc-shaped conductors, so that the first to eighth arc-shaped conductors operate in the first excited state.

In an embodiment, each of the first to eighth arc-shaped conductors may be configured in a resonant state, only one end of each of the first to eighth arc-shaped conductors is connected to a respective excitation source, and the excitation source is configured to apply a current to the first to eighth arc-shaped conductors, so that the first to eighth arc-shaped conductors operate in the first excited state.

In an embodiment, a middle point of each of the first to eighth arc-shaped conductors may be connected to a respective balun, and the baluns are configured to apply currents to the first to eighth arc-shaped conductors, so that the first to eighth arc-shaped conductors operate in the first excited state.

In an embodiment, at least one of the first arc-shaped conductor, the second arc-shaped conductor, the third arc-shaped conductor, and the fourth arc-shaped conductor, and the fifth arc-shaped conductor, the sixth arc-shaped conductor, the seventh arc-shaped conductor, and the eighth arc-shaped conductor may be connected to a resonant capacitor.

In an embodiment, a radial outer side of at least one of the first arc-shaped conductor, the second arc-shaped conductor, the third arc-shaped conductor, and the fourth arc-shaped conductor, and the fifth arc-shaped conductor, the sixth arc-shaped conductor, the seventh arc-shaped conductor, and the eighth arc-shaped conductor is provided with a dielectric material.

According to a second aspect of the present disclosure, provided is a radio frequency coil for a magnetic resonance imaging device, the radio frequency coil having a first end and a second end in an axial direction, and the radio frequency coil may comprise: a first conductor portion at the first end, the first conductor portion comprising a first arc-shaped conductor and a second arc-shaped conductor opposed in a radial direction; a second conductor portion at the second end; the second conductor portion comprising a third arc-shaped conductor and a fourth arc-shaped conductor opposed in the radial direction, wherein the first arc-shaped conductor and the third arc-shaped conductor are opposed in the axial direction, the second arc-shaped conductor and the fourth arc-shaped conductor are opposed in the axial direction, the radio frequency coil comprises two or more rung conductors, the two or more rung conductors are spaced apart from the first to fourth arc-shaped conductors, a first rung conductor among the two or more rung conductors is disposed between the first arc-shaped conductor and the third arc-shaped conductor, and a second rung conductor among the two or more rung conductors is disposed between the second arc-shaped conductor and the fourth arc-shaped conductor.

In an embodiment, further comprised are: the first to fourth arc-shaped conductors and the two or more rung conductors which may be configured to operate in a first excited state, wherein in the first excited state, currents at both ends of each of the arc-shaped conductors and rung conductors are less than a current at the center.

In an embodiment, both ends of each of the first to fourth arc-shaped conductors and the two or more rung conductors may be connected to different excitation sources, and the different excitation sources are configured to apply currents in opposite directions to the first to fourth arc-shaped conductors and the two or more rung conductors, so that the first to fourth arc-shaped conductors and the two or more rung conductors operate in the first excited state.

In an embodiment, each of the first to fourth arc-shaped conductors and the two or more rung conductors may be configured in a resonant state, only one end of each of the first to fourth arc-shaped conductors and the two or more rung conductors is connected to a respective excitation source, and the excitation source is configured to apply a current to the first to fourth arc-shaped conductors and the two or more rung conductors, so that the first to fourth arc-shaped conductors and the two or more rung conductors operate in the first excited state.

In an embodiment, a middle point of each of the first to fourth arc-shaped conductors and the two or more rung conductors may be connected to a respective balun, and the baluns are configured to apply currents to the first to fourth arc-shaped conductors and the two or more rung conductors, so that the first to fourth arc-shaped conductors and the two or more rung conductors operate in the first excited state.

In an embodiment, at least one of the first arc-shaped conductor, the second arc-shaped conductor, the third arc-shaped conductor and the fourth arc-shaped conductor, and the two or more rung conductors may be connected to a resonant capacitor.

In an embodiment, a radial outer side of at least one of the first arc-shaped conductor, the second arc-shaped conductor, the third arc-shaped conductor, and the fourth arc-shaped conductor, and the two or more rung conductors is provided with a dielectric material.

According to a third aspect of the present disclosure, provided is a resonance assembly for a magnetic resonance imaging system, wherein the resonance assembly may comprise: a radio frequency coil according to any one of the above items; a superconducting main coil configured to generate a polarized magnetic field; and a magnetic gradient generator configured to generate a magnetic field gradient in the axial direction, wherein the radio frequency coil is mounted in a coaxial relationship within the magnetic gradient generator.

In an embodiment, the magnetic gradient generator may be cylindrical, and the radio frequency coil is mounted inside the inner wall of the magnetic gradient generator.

### BRIEF DESCRIPTION OF THE DRAWINGS

The present disclosure can be better understood by means of the description of the exemplary embodiments of the present disclosure in conjunction with the drawings, in which:

FIG. 1 shows a schematic diagram of an example magnetic resonance imaging (MRI) system including a radio frequency (RF) coil.

FIG. 2 shows a perspective view of a bore of a gantry of an example MRI system.

FIG. 3 shows a perspective view of an RF coil according to an embodiment of the present disclosure.

FIG. 4 shows a schematic diagram of an arc-shaped conductor according to an embodiment of the present disclosure.

FIG. 5 shows a schematic diagram of an activation mode for an RF coil 300 according to an embodiment of the present disclosure.

FIGS. 6-8 show graphs of field strengths in different planes for an RF coil 300 according to an embodiment of the present disclosure.

FIG. 9 shows a B₁ image of a human body generated by an RF coil according to an embodiment of the present disclosure, and FIG. 10 shows a B₁ image of a human body generated by a conventional birdcage coil.

FIG. 11 shows a schematic diagram of an RF system 800 according to another embodiment of the present disclosure.

FIGS. 12 and 13 show schematic diagrams of example excitation modes employed by an RF coil 800 according to another embodiment of the present disclosure.

FIG. 14 shows a schematic diagram of an RF coil 1000 according to another embodiment of the present disclosure.

FIG. 15 and FIG. 16 show schematic diagrams of an activation mode for an RF coil 1000 according to another embodiment of the present disclosure.

### DETAILED DESCRIPTION

Specific embodiments of the present disclosure will be described below, but it should be noted that in the specific description of these embodiments, for the sake of brevity of description, it is impossible to describe all features of the actual embodiments of the present disclosure in detail in this description. It should be understood that in the actual implementation process of any implementation, just as in the process of any one engineering project or design project, a variety of specific decisions are often made to achieve specific goals of the developer and to meet system-related or business-related constraints, which may also vary from one implementation to another. Furthermore, it should also be understood that although efforts made in such development processes may be complex and tedious, for a person of ordinary skill in the art related to the content disclosed in the present disclosure, some design, manufacture, or production changes made on the basis of the technical content disclosed in the present disclosure are only common technical means, and should not be construed as the content of the present disclosure being insufficient.

References in the specification to “an embodiment”, “embodiment”, “example embodiment”, and so on indicate that the embodiment described may include a specific feature, structure, or characteristic, but the specific feature, structure, or characteristic is not necessarily included in every embodiment. Besides, such phrases do not necessarily refer to the same embodiment. Further, when a specific feature, structure, or characteristic is described in connection with an embodiment, it is believed that affecting such feature, structure, or characteristic in connection with other embodiments (whether or not explicitly described) is within the knowledge of those skilled in the art.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Unless otherwise defined, the technical or scientific terms used in the claims and the description should be as they are usually understood by those possessing ordinary skill in the technical field to which they belong. The terms “include” or “comprise” and similar words indicate that an element or object preceding the terms “include” or “comprise” encompasses elements or objects and equivalent elements thereof listed after the terms “include” or “comprise”, and do not exclude other elements or objects.

Furthermore, as used herein, the term “processor” or “processing unit” refers to any type of processing unit that can perform desired computations required by various implementations, such as a single-core or multi-core CPU, accelerated processing unit (APU), graphics board, DSP, FPGA, ASIC, or a combination thereof.

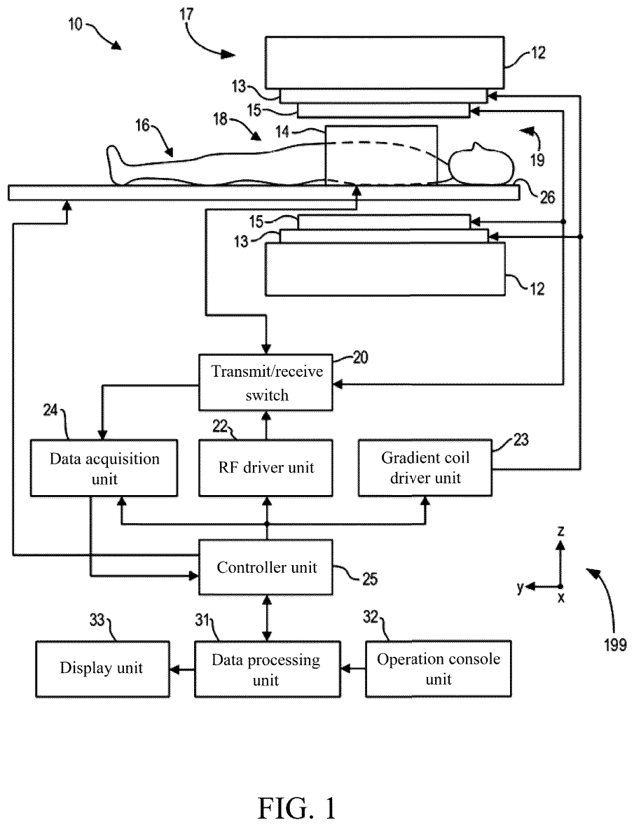

FIG. 1 shows an exemplary MRI system 10 including a magnetostatic magnet unit 12 (e.g., a superconducting main coil), a magnetic gradient generator 13, a local RF coil 14, a volume RF coil 15 (which may be referred to herein as a volume RF coil), a transmit/receive (T/R) switch 20, an RF signal driver 22, a gradient driver 23, a data acquisition unit 24, a controller unit 25, a patient table 26 (which may be referred to herein as a bed), a data processing unit 31, an operation console unit 32, and a display unit 33. In one embodiment, the superconducting main coil 12, the magnetic gradient generator 13 and the volume RF coil may together form a resonance assembly for a magnetic resonance imaging system. The local RF coil 14 is a surface coil configured to get close to a surface of an anatomical structure of a subject 16 (e.g., a patient) to be scanned by the MRI system 10. The volume RF coil 15 is a coil configured to transmit an RF signal (e.g., a radio-frequency electromagnetic wave), and the local RF coil 14 is configured to receive an RF signal. Thus, the volume RF coil 15 and the local RF coil 14 are spatially separated from each other, but may be electromagnetically coupled to each other. In some examples, the local RF coil 14 and/or the volume RF coil 15 may transmit and receive the RF signal. Example operation modes for coils (e.g., the local RF coil 14 and the volume RF coil 15) are described further below.

The MRI system 10 includes the patient table 26 for placing the subject 16 (e.g., a patient) thereon. By moving the patient table 26, the subject 16 may be moved inside and outside an imaging space 18. The imaging space 18 may be positioned within a bore 19 in a gantry 17 of the MRI system 10. In some examples, the controller unit 25 may send a control signal (e.g., an electrical signal) to the operation console unit 32 and/or the display unit 33 to indicate, to an operator (e.g., a user, a technician, etc.) of the MRI system 10, the position of the patient table 26 within the imaging space 18.

The operation console unit 32 includes a user input device, such as a keyboard and a mouse. The operation console unit 32 is a region used by the operator to, for example, input an imaging protocol (for example, a parallel imaging protocol), and set an imaging series to be performed. Data on the imaging protocol is inputted to the operation console unit 32 by the operator, and an imaging serial execution region is output to the controller unit 25.

The display unit 33 includes a graphic display device (e.g., a computer screen), and displays an image on the graphic display device based on the control signal received from the controller unit 25. The display unit 33 displays, for example, an image regarding an input item, and from the operation console unit 32, the operator inputs operation data regarding the input item. The display unit 33 also displays a slice image of the subject 16 generated by the data processing unit 31.

The data processing unit 31 includes a computer and a recording medium (e.g., a hard disc drive) on which a program executable by the computer to perform predetermined data processing is recorded. The data processing unit 31 is electrically coupled to the controller unit 25, and performs data processing based on a control signal received from the controller unit 25. The data processing unit 31 is also connected to the data acquisition unit 24 and generates spectral data by applying various image processing operations to magnetic resonance (MR) signals outputted from the data acquisition unit 24 (described in more detail below).

The magnetostatic magnet unit 12 includes an annular superconducting main coil coupled to and positioned inside an annular vacuum vessel (e.g., the gantry 17). The superconducting main coil defines a cylindrical space (e.g., the bore 19) surrounding the subject 16 and generates a polarizing magnetic field B₀ having a substantially constant magnitude and direction within the cylindrical space (e.g., in the y-axis direction within the cylindrical space, as indicated by a reference axis 199). A static magnetic field generated by an electromagnet may also be referred to herein as a uniform magnetic field.

The MRI system 10 further includes the magnetic gradient generator 13 that generates an additional magnetic field (which may be referred to herein as a gradient magnetic field) in the imaging space 18 in order to correlate an MR signal received by the local RF coil 14 with three-dimensional position information. For example, the gradient magnetic field generated by the magnetic gradient generator 13 may have different magnitudes (e.g., different field strengths) at different locations within the imaging space 18. The magnetic gradient generator 13 includes three gradient coil systems. Each gradient coil system adjusts the magnitude of the gradient magnetic field along one of three perpendicular directions. For example, a first gradient coil system adjusts the magnitude of the gradient magnetic field in a frequency encoding direction, a second gradient coil system adjusts the magnitude of the gradient magnetic field in a phase encoding direction, and a third gradient coil system adjusts the magnitude of the gradient magnetic field in a slice selection direction. The frequency encoding direction, the phase encoding direction, and the slice selection direction may be defined based on input from a user (e.g., the operator) of the MRI system 10 (e.g., via the operation console unit 32). More specifically, the magnetic gradient generator 13 adjusts the magnitude of the gradient magnetic field in the slice selection direction of the subject 16 in response to input from the operator. The local RF coil 14 then transmits an RF pulse to a selected slice of the subject 16 and excites the slice (e.g., excites spins of hydrogen nuclei within the selected slice of the subject 16). The magnetic gradient generator 13 adjusts the magnitude of the gradient magnetic field in the phase encoding direction of the subject 16 to perform phase encoding on an MR signal emitted by the slice excited by the RF pulse. Then, the magnetic gradient generator 13 adjusts the magnitude of the gradient magnetic field in the frequency encoding direction of the subject 16 to perform frequency encoding on the MR signal emitted by the slice excited by the RF pulse.

The gradient driver 23 drives the magnetic gradient generator 13 based on a control signal received from the controller unit 25, thereby generating the gradient magnetic field in the imaging space 18. The gradient driver 23 includes three driver circuit systems (not shown) corresponding to the three gradient coil systems included in the magnetic gradient generator 13 (as described above).

An RF coil of the MRI system 10 (e.g., the local RF coil 14 and/or the volume RF coil 15) may transmit an electromagnetic pulse signal to the subject 16 located within the imaging space 18, with the polarizing magnetic field B₀ and the gradient magnetic field extending through the imaging space 18. The local RF coil 14 is shaped, for example, to encompass a region of the subject 16 to be imaged. In some examples, the local RF coil 14 may be referred to as a surface coil or a receiver coil. The MRI system 10 receives the MR signal from the subject 16 (e.g., via the data acquisition unit 24 coupled to the RF coil) and processes the MR signal (e.g., via the data processing unit 31) in order to construct an image of the slice of the subject 16 based on the received MR signal.

For example, during a state in which the subject 16 is positioned to be scanned by the MRI system 10 (e.g., during a state in which the subject 16 is within the imaging space 18), spins of hydrogen nuclei within a tissue of the subject 16 may coincide with an initial magnetization vector generated by a combination of the polarizing magnetic field B₀ and the gradient magnetic field. The local RF coil 14 may transmit an RF pulse as an electromagnetic wave to the subject 16 based on a control signal from the controller unit 25. The RF pulse transmitted to the subject 16 generates a radio frequency magnetic field within the slice (e.g., selected by the operator of the MRI system 10) of the subject 16 to be imaged. The radio frequency magnetic field excites spins of hydrogen nuclei in the slice of the subject 16, and causes the spins to be consistent with the magnetization vector changing relative to the initial magnetization vector. As spins of excited hydrogen nuclei in the slice of the subject 16 undergo relaxation and return to being consistent with the initial magnetization vector, the local RF coil 14 receives an electromagnetic wave, as the MR signal, generated from the tissue of the subject 16.

The volume RF coil 15 may alternatively (or additionally) be used to generate a radio frequency magnetic field similar to that described above with reference to the local RF coil 14. For example, the volume RF coil 15 is positioned to surround the imaging space 18 and may generate the RF pulse in a direction orthogonal to the direction of a uniform magnetic field generated by the magnetostatic magnet unit 12 within the imaging space 18, so as to excite the hydrogen nuclei in the subject 16. Unlike the local RF coil 14 which may be disconnected from the MRI system 10 and replaced with a different local RF coil, the volume RF coil 15 is fixedly attached to and coupled to the MRI system 10. Further, local coils, such as those including the local RF coil 14, may each transmit a signal to and/or receive a signal (e.g., transmit the RF signal and/or receive the MR signal) from a local region of the subject 16 (e.g., a particular anatomical structure or a slice of the subject 16), while the volume RF coil 15 may transmit a signal to and/or receive a signal from a larger portion of the subject 16 (e.g., the entire body of the subject 16).

The RF signal driver 22 which is electrically coupled to a coil (e.g., the volume RF coil 15 and/or the local RF coil 14) via the T/R switch 20 includes a gate modulator (not shown), an RF power amplifier (not shown), and an RF oscillator (not shown) for driving the local RF coil 14 and/or the volume RF coil 15 to form the radio frequency magnetic field B₁ in the imaging space 18 (as described above). The RF signal driver 22 modulates an RF signal received from the RF oscillator into a signal having a predetermined timing and a predetermined envelope via the gate modulator, wherein the RF signal is based on a control signal from the controller unit 25. The RF signal modulated by the gate modulator is amplified by the RF power amplifier and then outputted to the local RF coil 14 and/or the volume RF coil 15.

The T/R switch 20 may selectively electrically couple the local RF coil 14 and/or the volume RF coil 15 to the data acquisition unit 24 when operating in a receiving mode, and may selectively electrically couple the local RF coil 14 and/or the volume RF coil 15 to the RF signal driver 22 when operating in a transmitting mode. During a state in which both the local RF coil 14 and the volume RF coil 15 are used for a single scan (e.g., during a state in which the local RF coil 14 is configured to receive the MR signal and the volume RF coil 15 is configured to transmit the RF signal), the T/R switch 20 may direct a control signal from the RF signal driver 22 to the volume RF coil 15 and direct a received MR signal from the local RF coil 14 to the data acquisition unit 24. As described above, the volume RF coil 15 may be configured to operate in a transmitting-only mode, a receiving-only mode, or a transmitting-and-receiving mode. The local RF coil 14 may be configured to operate in a transmitting-and-receiving mode or a receiving-only mode.

The data acquisition unit 24 includes a preamplifier (not shown), a phase detector (not shown), and an analog/digital converter (not shown) for acquiring the magnetic resonance signal received by the local RF coil 14 and/or the volume RF coil 15. In the data acquisition unit 24, the phase detector uses the output from the RF oscillator of the RF signal driver 22 as a reference signal to perform phase detection on the MR signal received by the local RF coil 14 and/or the volume RF coil 15 (wherein the MR signal is amplified by the preamplifier), and outputs an analog MR signal subjected to phase detection to the analog/digital converter for conversion into a digital signal. The digital signal thus obtained is outputted to the data processing unit 31 electrically coupled to the controller unit 25.

The controller unit 25 includes a computer and a recording medium that records a program to be executed by the computer. The program, when being executed by the computer, causes various parts of a system to perform an operation corresponding to a predetermined scan. The recording medium may include, for example, a read-only memory (ROM), a floppy disk, a hard disk, an optical disk, a magneto-optical disk, a CD-ROM, or a non-volatile memory card. The controller unit 25 is connected to the operation console unit 32 and processes an operating signal inputted to the operation console unit 32 (e.g., inputted by the operator of the MRI system 10), and, in addition, controls the patient table 26, the RF signal driver 22, the gradient driver 23, and the data acquisition unit 24 by outputting control signals to the same. The controller unit 25 also controls the data processing unit 31 and the display unit 33 based on the operating signal received from the operation console unit 32 so as to obtain a desired image.

During a scan (e.g., the subject 16 is imaged according to the example described above), a coil-interface cable (not shown) may be used to transmit a signal between the RF coil (e.g., the local RF coil 14 and the volume RF coil 15) and other aspects of the processing system (e.g., the data acquisition unit 24, the controller unit 25, etc.), for example, to control the RF coil and/or to receive information from the RF coil. As previously described, in one example, the volume RF coil 15 may transmit the RF signal and the local RF coil 14 may receive the MR signal. The local RF coil 14 and/or the volume RF coil 15 may include a coil for transmitting an RF excitation signal (a “transmitter coil”) and a coil for receiving an MR signal transmitted by an imaging subject (a “receive coil”). In some examples, the transmitter coil and the receive coil may be the same coil (e.g., be configured to transmit the RF excitation signal and receive the MR signal), so that the coil is a single mechanical structure or an array of structures, where the transmitting/receiving mode of the coil may be switched by an auxiliary circuit (e.g., the T/R switch 20). In other examples, the volume RF coil 15 and the local RF coil 14 may be separate structures physically coupled to each other via a data acquisition unit or other processing unit.

In some examples (e.g., examples in which the transmitter coil and the receive coil are not the same coil), it may be desirable to configure the receive coil to be mechanically and electrically isolated from the transmitter coil to obtain improved image quality. In one example, the receive coil (e.g., the local RF coil 14) may be configured to receive the MR signal for a duration of time after the RF signal is transmitted from the transmitter coil (e.g., the volume RF coil 15). However, within the duration of time in which the transmitter coil transmits the RF signal, it may be desirable to electromagnetically decouple the receive coil from the transmitter coil, so that the receive coil does not resonate with the transmitter coil (e.g., so that the receive coil does not receive the RF signal from the transmitter coil). By electromechanically decoupling (e.g., deactivating) the receive coil during transmission of the RF signal by the transmitter coil, it is possible to reduce the amount of noise generated within the auxiliary circuit coupled to the receive coil and to produce improved image quality.

In some examples, the volume RF coil 15 may be positioned in a birdcage apparatus (which may be referred to herein as a birdcage coil assembly) that is coupled to an outer surface of the bore 19 of the gantry 17 and surrounds the imaging space 18.

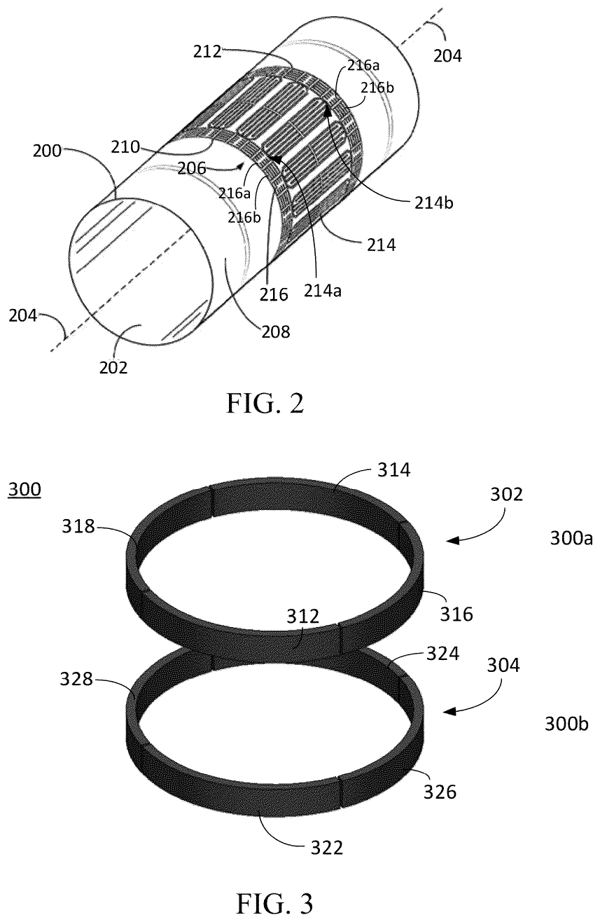

FIG. 2 shows a bore 200 of a gantry of an example MRI system including an RF coil 206 (similar to the bore 19 of the gantry 17 of the MRI system 10 shown in FIG. 1 and described above). An imaging space is formed within the interior 202 of the bore 200 for imaging of a subject (e.g., a patient positioned on a table, such as the table 26 shown in FIG. 1 and described above). In the example shown in FIG. 2, the bore 200 is cylindrical, and has a central axis 204. In other examples, the bore 200 may have a different shape (e.g., a shape having a rectangular cross-section).

The RF coil 206 is a volume RF coil similar to the volume coil 15 shown in FIG. 1 and described above. The RF coil 206, about the central axis 204, is circumferentially coupled to an outer surface 208 of the bore 200 and includes a first end ring 210 and a second end ring 212 coupled via a plurality of rung conductors 214. The first end ring 210 and the second end ring 212 are annular, which are shaped to surround the perimeter of the bore 200 to image the patient within the interior 202 (e.g., imaging as described above with reference to FIG. 1). Each of the first end ring 210 and the second end ring 212 may be formed of a material that is not electrically conductive (e.g., an electrical insulator) and includes a plurality of conductive portions 216. Specifically, the plurality of conductive portions 216 may be divided into first conductive portions 216a and second conductive portions 216b. In each of the first end ring 210 and the second end ring 212, a plurality of first conductive portions 216a and a plurality of second conductive portions 216b that are alternately disposed are included.

Each of the plurality of first conductive portions 216a of the first end ring 210 is coupled to a corresponding one of the plurality of first conductive portions 216a of the second end ring 212 by a rung conductor 214. The plurality of first conductive portions 216a of the first end ring 210 may be mechanically and electrically coupled (e.g., soldered, fused, etc.) to the rung conductors 214 at first ends 214a of the rung conductors 214, and similarly, the plurality of first conductive portions 216a of the second end ring 216 may be mechanically and electrically coupled to the rung conductors 214 at second ends 214b of the rung conductors 214. In this configuration, a current may flow between the conductive portions 216 of the first end ring 210 and the conductive portions 216 of the second end ring 212 via the rung conductors 214.

Although the second conductive portions 216b are not directly coupled to the rung conductors 214, the second conductive portions 216b may be mechanically and electrically coupled to each adjacent conductive portion. For example, the second conductive portions 216b are mechanically and electrically coupled to two adjacent first conductive portions 216a along an outer surface of the first end ring 210. In this configuration, the conductive portions at the outer surface of the first end ring 210 are electrically coupled to each other, so that a current may flow through each portion (e.g., during a state where the MRI system is operated to image a patient, as described above with reference to FIG. 1).

When the B₀ field has a field strength less than 1 T, a dielectric constant of a human body placed in an imaging apparatus has little influence on the radio frequency magnetic field B1. However, when the field strength of the B₀ field increases, for example, approaches or is greater than 1.5 T, the dielectric constant and conductivity of the human body may generate a significant impact, distorting the radio frequency magnetic field B1. On that basis, the present disclosure provides an RF coil which, in comparison with conventional birdcage coils (e.g., the RF coil 206 in FIG. 2), can generate a radio-frequency magnetic field on a human body which is comparable to that of the birdcage coil, while providing additional advantages in comparison with a birdcage coil.

FIG. 3 shows a perspective view of an RF coil according to an embodiment of the present disclosure. As shown in FIG. 3, the RF coil 300 has a first end 300a and a second end 300b in an axial direction (a z-axis direction). The RF coil 300 includes a first conductive portion 302 at the first end 300a and a second conductive portion 304 at the second end 300b. The first conductive portion 302 includes a first arc-shaped conductor 312 and a second arc-shaped conductor 314 opposed in a radial direction. The first conductor portion 302 further includes a fifth arc-shaped conductor 316 and a sixth arc-shaped conductor 318 opposed in the radial direction, the fifth arc-shaped conductor 316 and the sixth arc-shaped conductor 318 are respectively disposed on two sides between the first arc-shaped conductor 312 and the second arc-shaped conductor 314, and the first arc-shaped conductor 312, the fifth arc-shaped conductor 316, the second arc-shaped conductor 314, and the sixth arc-shaped conductor 318 together form a circular ring shape and are not connected to each other. Preferably, each of the first arc-shaped conductor, the fifth arc-shaped conductor 316, the second arc-shaped conductor 314, and the sixth arc-shaped conductors 318 may have a length of less than ¼ arc.

The second conductive portion 304 includes a third arc-shaped conductor 322, a fourth arc-shaped conductor 324, a seventh arc-shaped conductor 326, and an eighth arc-shaped conductor 328. The structure of the arc-shaped conductors of the second conductive portion 304 corresponds to the structure of the arc-shaped conductors of the first conductive portion 302. The third arc-shaped conductor 322 and the fourth arc-shaped conductor 324 are radially opposed, the seventh arc-shaped conductor 326 and the eighth arc-shaped conductor 328 are radially opposed and are respectively disposed on two sides between the third arc-shaped conductor 322 and the fourth arc-shaped conductor 324, and the third arc-shaped conductor 322, the seventh arc-shaped conductor 326, the fourth arc-shaped conductor 324, and the eighth arc-shaped conductor 328 together form a circular ring shape and are not connected to each other. Preferably, each of the third arc-shaped conductor 322, the seventh arc-shaped conductor 326, the fourth arc-shaped conductor 324, and the eighth arc-shaped conductor 328 may have a length of less than ¼ arc.

In the RF coil 300 shown in FIG. 3, there are no rung conductors (e.g., as described with reference to FIG. 2) for connecting the first conductive portion 302 to the second conductive portion 304.

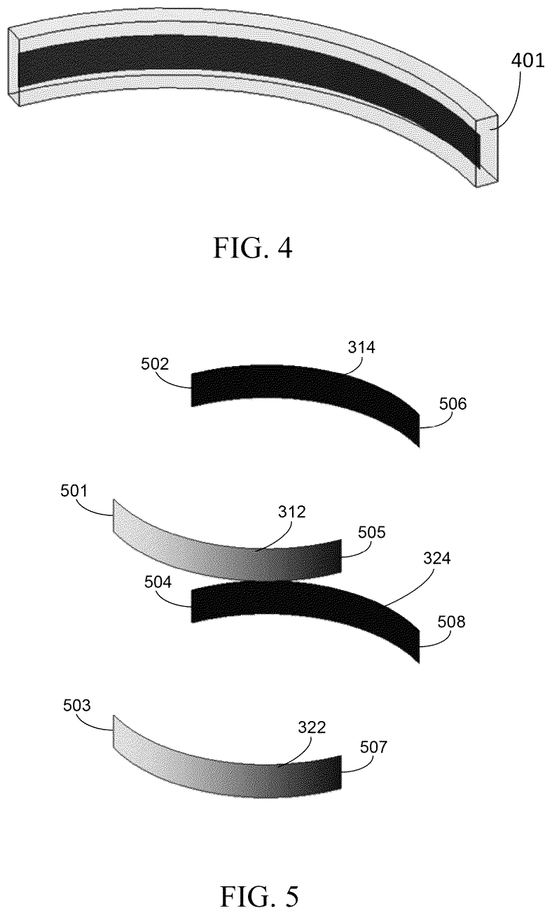

FIG. 4 shows a schematic diagram of an arc-shaped conductor according to an embodiment of the present disclosure. As shown in FIG. 4, a dielectric material 401 may be wrapped outside the arc-shaped conductor, and the dielectric material may be attached to an RF shielding layer disposed at an innermost side of a gradient coil (e.g., the magnetic gradient generator 13 described with reference to FIG. 1), thereby achieving shielding and resonance. As an example, the dielectric material 401 may be a resin material. In addition, resonance may be achieved by wrapping a dielectric material and an RF shielding layer outside each of the first arc-shaped conductor 312 to the eighth arc-shaped conductor 328, or resonance may be achieved by providing a resonant capacitor and an RF shielding layer at both ends of each of the first arc-shaped conductor 312 to the eighth arc-shaped conductor 328.

FIG. 5 shows a schematic diagram of an activation mode for an RF coil 300 according to an embodiment of the present disclosure. To obtain a circularly polarized B1 field, it is necessary to generate a group of orthogonal magnetic field components. In this embodiment, the first arc-shaped conductor 312, the second arc-shaped conductor 314, the third arc-shaped conductor 322, and the fourth arc-shaped conductor 324 may be used as a first group of arc-shaped conductors, and the fifth arc-shaped conductor 316, the sixth arc-shaped conductor 318, the seventh arc-shaped conductor 326, and the eighth arc-shaped conductor 328 may be used as a second group of arc-shaped conductors. The first group of arc-shaped conductors and the second group of arc-shaped conductors both operate in a first excited state, i.e., currents at both ends of each arc-shaped conductor are less than a current at the center. In this way, the first group of arc-shaped conductors and the second group of arc-shaped conductors generate magnetic field components orthogonal to each other, so that a circularly polarized B1 field can be formed.

As an example implementation of the first excited state, both ends of a conductor may be connected to different excitation sources, and the different excitation sources are used to apply currents in opposite directions to both ends of the conductor. Referring to FIG. 5, both end portions 501 and 505 of the first arc-shaped conductor 312 may be connected to two different excitation sources, and have currents applied thereto in opposite directions by the two excitation sources. Both end portions 502 and 506 of the second arc-shaped conductor 314 may be connected to two different excitation sources, and have currents applied thereto in opposite directions by the two excitation sources. Both end portions 503 and 507 of the third arc-shaped conductor 322 may be connected to two different excitation sources, and have currents applied thereto opposite directions by the two excitation sources. Both end portions 504 and 508 of the fourth arc-shaped conductor 324 may be connected to two different excitation sources, and have currents applied thereto in opposite directions by the two excitation sources. In some embodiments, both ends of each arc-shaped conductor may have currents having equal magnitudes applied thereto. In some embodiments, the two excitation sources connected to each arc-shaped conductor may be different from those connected to the other arc-shaped conductors. In some embodiments, one excitation source may apply a current to one end of the first to fourth arc-shaped conductors, and another excitation source may apply a current in an opposite direction to the other end of the first to fourth arc-shaped conductors.

As another example implementation of the first excited state, respective arc-shaped conductors may be in a resonant state. This can be achieved by forming a dipole by means of a terminated capacitor or a dielectric material. In the resonant state, it is only necessary to input a current to one end of each arc-shaped conductor. As shown in FIG. 5, one excitation source may be used to drive the first arc-shaped conductor 312 via the end 501, the second arc-shaped conductor 314 via the end 502, the third arc-shaped conductor 322 via the end 507, and the fourth arc-shaped conductor 324 via the end 508. In some embodiments, each arc-shaped conductor may be driven by a different excitation source. In some embodiments, the first to fourth arc-shaped conductors may be driven by the same excitation source.

As yet another example implementation of the first excited state, a balun may be connected at a middle point of each arc-shaped conductor. The baluns connected to individual arc-shaped conductors are different from each other. By providing differential signals to the arc-shaped conductors by using the baluns, the arc-shaped conductors may be enabled to operate in the first excited state.

FIG. 5 only shows the first group of arc-shaped conductors composed of the first to fourth arc-shaped conductors. It should be understood that the second group of arc-shaped conductors composed of the fifth to eighth arc-shaped conductors may also be enabled to be in the first excited state in the same manner. In addition, it should be understood that the present disclosure also includes a solution to implement the first excitation mode by means of other circuit configurations. The above description of a specific circuit configuration is only an example and should not be construed as limiting the scope of the present disclosure.

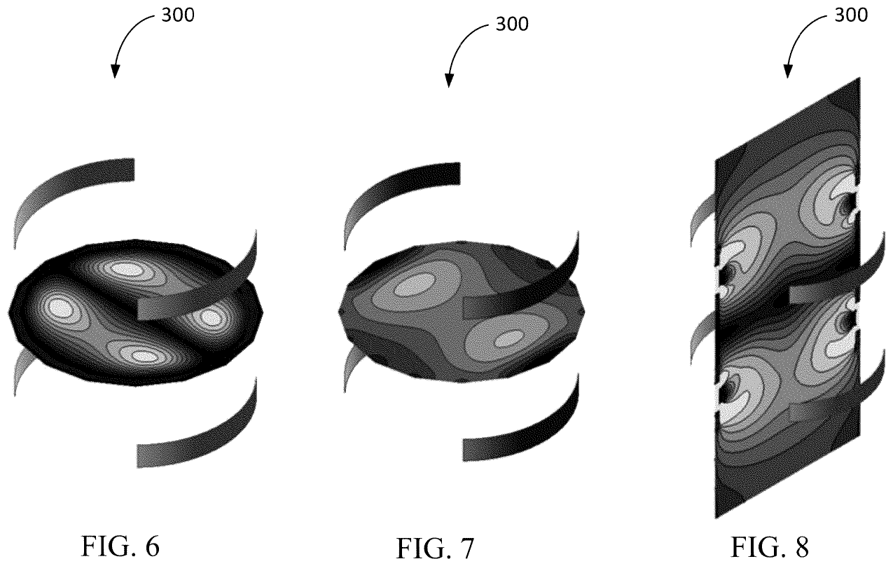

FIGS. 6-8 show graphs of field strengths in different planes for an RF coil 300 according to one embodiment of the present disclosure. Here, FIGS. 6-7 show an electric field (an E field) intensity and a magnetic field (an H field) intensity in a plane formed by an X axis and a Y axis, and FIG. 8 shows an electric field (the E field) intensity in a plane formed by the Y axis and a Z axis. The RF coil 300 is driven in a manner described with reference to FIG. 5, i.e., each of the first group of arc-shaped conductors (including the first arc-shaped conductor 312, the second arc-shaped conductor 314, the third arc-shaped conductor 322, and the fourth arc-shaped conductor 324) is driven with a high current density at the center, and a low current density at both ends, and with the same phase, to generate a linear H field. At the same time, the second group of arc-shaped conductors, including the fifth arc-shaped conductor 316, the sixth arc-shaped conductor 318, the seventh arc-shaped conductor 326, and the eighth arc-shaped conductor 328, is driven with a 90-degree offset from the first group of arc-shaped conductors to generate an orthogonal H field similar to a conventional birdcage coil, thereby generating a circularly polarized B₁ field.

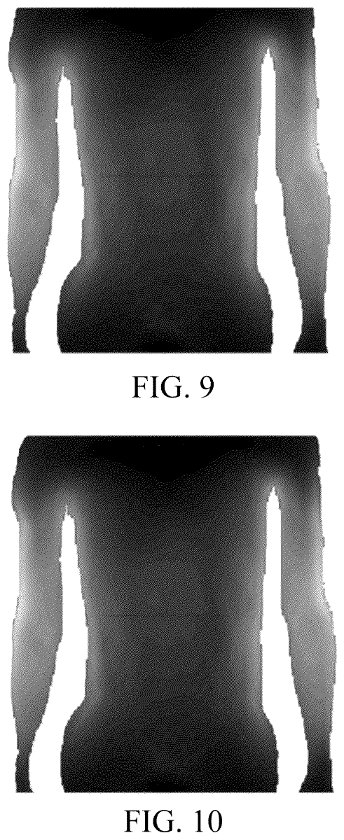

FIG. 9 shows a B₁ image of a human body generated by an RF coil according to an embodiment of the present disclosure, and FIG. 10 shows a B₁ image of a human body generated by a conventional birdcage coil. It can be seen from FIG. 9 and FIG. 10 that, compared with the conventional birdcage coil, although the RF coil 300 of FIG. 3 has a greatly simplified mechanical structure, when a human body is in the imaging space and the B₀ field is large enough (for example, approximately 1.5 T and higher), the frequency of the radio frequency field B1 is close to or higher than 63 MHz, and the human body generates a significant influence on a radio frequency field distribution, thus exhibiting an imaging effect comparable to that of the conventional birdcage coil. In addition, the conventional birdcage coil requires a support, the birdcage coil is mounted outside the support, and then the support and the birdcage coil are both mounted to an inner side of a gradient coil structure, and are also maintained at a certain distance from the gradient coil structure. However, the RF coil of the present disclosure can be directly mounted on the inner wall of the magnetic gradient generator. Thus, costs can be reduced, mounting steps are simplified, and maintenance during later use is easier. Further, a driver amplifier is very sensitive to a load change of a coil (which may be evaluated based on VSWR). In the conventional birdcage coil, due to the complex resonance thereof, it is difficult to predict a load change thereof, because the change may be caused by various factors, such as the position of a subject under examination relative to the birdcage coil, and also does not change regularly with the volume or the weight of the subject under examination. In contrast, the RF coil structure of the present disclosure has a simple structure, and the structure between conductors is relatively independent. Thus, the RF coil has a load which is also relatively predictable.

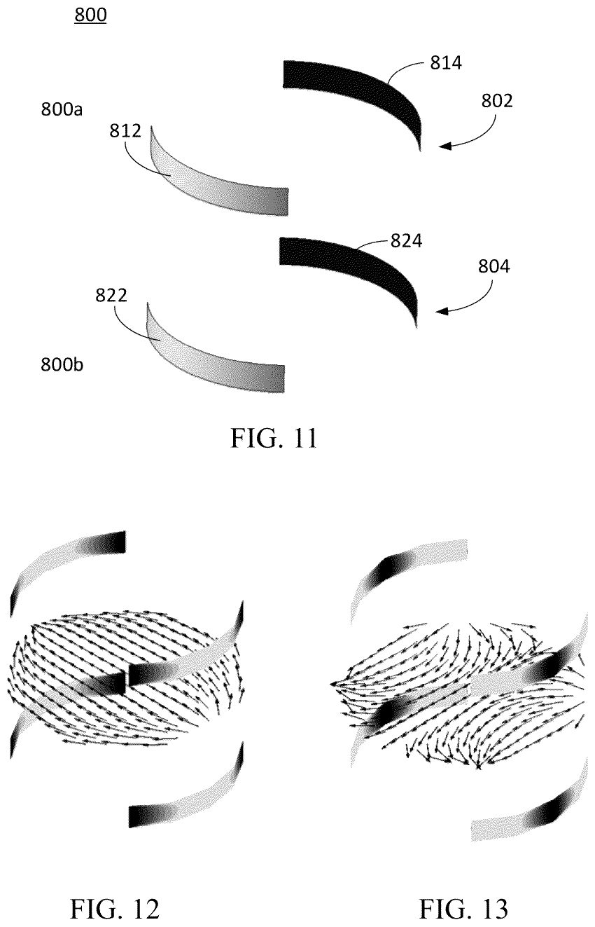

FIG. 11 shows a schematic diagram of an RF coil 800 according to another embodiment of the present disclosure. The RF coil 800 has a structure similar to that of the RF coil 300 described with reference to FIG. 3, except that the fifth arc-shaped conductor 316, the sixth arc-shaped conductor 318, the seventh arc-shaped conductor 326, and the eighth arc-shaped conductor 328 may be omitted compared to the RF coil 300. The RF coil 800 includes a first conductive portion 802 at a first end 800a and a second conductive portion 804 at a second end 800b. The first conductive portion 802 includes a first arc-shaped conductor 812 and a second arc-shaped conductor 814, and the second conductive portion 804 includes a third arc-shaped conductor 822 and a fourth arc-shaped conductor 824. The first arc-shaped conductor 812 and the second arc-shaped conductor 814 are opposed in a radial direction, the third arc-shaped conductor 822 and the fourth arc-shaped conductor 824 are opposed in the radial direction, the first arc-shaped conductor 812 and the third arc-shaped conductor 822 are opposed in an axial direction, and the second arc-shaped conductor 814 and the fourth arc-shaped conductor 824 are opposed in the axial direction. Preferably, the first arc-shaped conductor 812 and the second arc-shaped conductor 814 are opposed in the radial direction, and each of the third arc-shaped conductor 822 and the fourth arc-shaped conductor 824 may have a length of less than ½ arc. In the present embodiment, since a group of arc-shaped conductors is omitted, the first arc-shaped conductor 812, the second arc-shaped conductor 814, the third arc-shaped conductor 822, and the fourth arc-shaped conductor 824 need to simultaneously generate magnetic field components in two orthogonal directions.

FIGS. 12 and 13 show schematic diagrams of an example excitation mode employed by an RF coil 800 according to another embodiment of the present disclosure. In this embodiment, each of the first arc-shaped conductor 812, the second arc-shaped conductor 814, the third arc-shaped conductor 822, and the fourth arc-shaped conductor 824 operates in the first excitation mode and the second excitation mode simultaneously to generate magnetic field components in two orthogonal directions. The first excitation mode causes the first arc-shaped conductor 812, the second arc-shaped conductor 814, the third arc-shaped conductor 822, and the fourth arc-shaped conductor 824 to generate a magnetic field component in an orthogonal direction, and the second excitation mode causes the first arc-shaped conductor 812, the second arc-shaped conductor 814, the third arc-shaped conductor 822, and the fourth arc-shaped conductor 824 to generate a magnetic field component in another orthogonal direction. The first excitation mode, as described above, enables currents at both ends of each conductor that are smaller than a current at the center. The second excitation mode enables the currents at both ends of each conductor that are greater than the current at the center, thereby generating a magnetic field in an orthogonal direction relative the first excitation mode. FIG. 12 shows a current pattern in the first excitation mode. Specifically, each of the first arc-shaped conductor 812, the second arc-shaped conductor 814, the third arc-shaped conductor 822, and the fourth arc-shaped conductor 824 has a high current density at the center, and a low current density at both ends, generating a magnetic field in one direction at this point. FIG. 13 shows a current pattern in the second excitation mode, that is, each of the first arc-shaped conductor 812, the second arc-shaped conductor 814, the third arc-shaped conductor 822, and the fourth arc-shaped conductor 824 has a high current density at the ends, and a low current density at the center, generating a magnetic field in another orthogonal direction at this point.

To make the first arc-shaped conductor 812, the second arc-shaped conductor 814, the third arc-shaped conductor 822, and the fourth arc-shaped conductor 824 operate in the first excited state and the second excited state simultaneously, two groups of mutually independent excitation sources may be connected in parallel at both ends of a same conductor and respectively provide currents in two states. The two excited states may have phases which differ by 90 degrees. The first arc-shaped conductor 812, the second arc-shaped conductor 814, the third arc-shaped conductor 822, and the fourth arc-shaped conductor 824 may be subjected to circuit configuration according to a desired excitation state. Specifically, the first excited state may be obtained by using the example implementation described above with reference to FIG. 5, and details are not described herein again. As an example implementation of the second excited state, different excitation sources may be used to apply currents in a same direction to the first arc-shaped conductor 812, the second arc-shaped conductor 814, the third arc-shaped conductor 822, and the fourth arc-shaped conductor 824. In some embodiments, the magnitudes of currents applied from both ends may be the same. Thus, the first arc-shaped conductor 812, the second arc-shaped conductor 814, the third arc-shaped conductor 822, and the fourth arc-shaped conductor 824 are caused to operate in the first excited state and the second excited state simultaneously by means of two groups of circuit configurations.

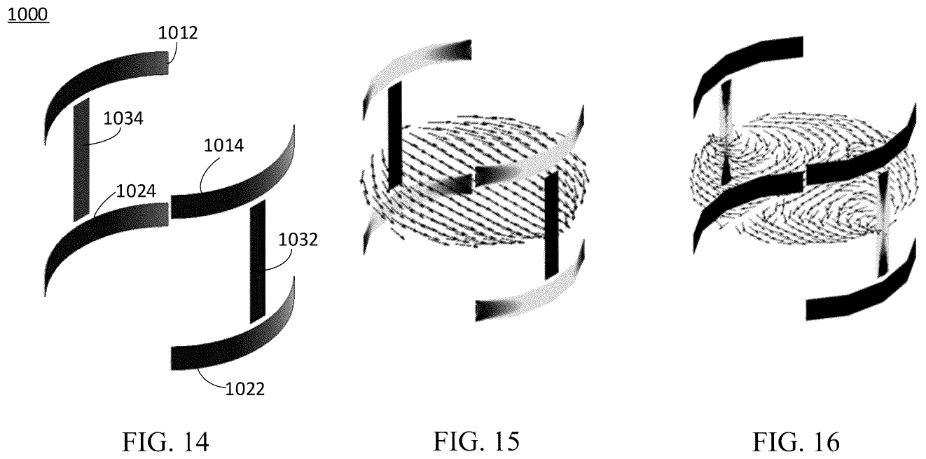

FIG. 14 shows a schematic diagram of an RF coil 1000 according to another embodiment of the present disclosure. The RF coil 1000, similar to the RF coil 800, includes a first arc-shaped conductor 1012, a second arc-shaped conductor 1014, a third arc-shaped conductor 1024, and a fourth arc-shaped conductor 1022. The arrangement of the first arc-shaped conductor 1012, the second arc-shaped conductor 1014, the third arc-shaped conductor 1024, and the fourth arc-shaped conductor 1022 of the RF coil 1000 is similar to that of the first arc-shaped conductor 812 to the fourth arc-shaped conductor 824 of the RF coil 800, and details are not described herein again. In addition, the RF coil 1000 further includes two rung conductors, that is, a first rung conductor 1034 and a second rung conductor 1032. The first rung conductor 1034 is located between the first arc-shaped conductor 1012 and the third arc-shaped conductor 1024 and is spaced apart from the first arc-shaped conductor 1012 and the third arc-shaped conductor 1024, and the second rung conductor 1032 is connected between the second arc-shaped conductor 1014 and the fourth arc-shaped conductor 1022 and is spaced apart from the second arc-shaped conductor 1014 and the fourth arc-shaped conductor 1022. The first rung conductor 1034 and the second rung conductor 1032 are used to provide a magnetic field in an orthogonal direction, and the first arc-shaped conductor 1012, the second arc-shaped conductor 1014, the third arc-shaped conductor 1024, and the fourth arc-shaped conductor 1022 are used to provide a magnetic field in another orthogonal direction. In some embodiments, a greater number of rung conductors may be included, which are not in contact with the first arc-shaped conductor 1012, the second arc-shaped conductor 1014, the third arc-shaped conductor 1024, and the fourth arc-shaped conductor 1022, and may be excited to provide a magnetic field in one orthogonal direction.

FIG. 15 and FIG. 16 show schematic diagrams of an activation mode for an RF coil 1000 according to another embodiment of the present disclosure. In this embodiment, a magnetic field in an orthogonal direction is generated by driving the first arc-shaped conductor 1012, the second arc-shaped conductor 1014, the third arc-shaped conductor 1024, and the fourth arc-shaped conductor 1022, and a magnetic field in another orthogonal direction is generated by driving the first rung conductor 1034 and the second rung conductor 1032. The first arc-shaped conductor 1012, the second arc-shaped conductor 1014, the third arc-shaped conductor 1024, the fourth arc-shaped conductor 1022, the first rung conductor 1034, and the second rung conductor 1032 all operate in the first excitation mode described above. FIG. 15 illustrates a current pattern and a generated magnetic field for the first arc-shaped conductor 1012, the second arc-shaped conductor 1014, the third arc-shaped conductor 1024, and the fourth arc-shaped conductor 1022 in the first excited state. FIG. 16 shows a current pattern and a generated magnetic field for the first rung conductor 1034 and the second rung conductor 1032 in the first excited state. The first excited state may be generated in the manner described above with reference to FIG. 5, and details are not described herein again.

As previously mentioned, in the present disclosure, the RF coil is designed by considering a dielectric effect generated by a human body under a sufficiently large B₀ field. The obtained RF coil exhibits imaging performance comparable to that of a conventional birdcage coil. In addition, the RF coil of the present disclosure has a simple structure and is convenient to mount, and can have an expected load change compared to the conventional birdcage coil, thus facilitating the design of an amplifier and easy maintenance.

While the present disclosure has been described with reference to certain implementations, it should be understood by those skilled in the art that various changes may be made and equivalents may be substituted without departing from the scope of the present disclosure. Furthermore, numerous modifications may be made to adapt particular circumstances or materials to the teachings of the present disclosure without departing from the scope thereof. Therefore, the present disclosure is not intended to be limited to the specific embodiments disclosed, but shall encompass all embodiments falling within the scope of the appended claims.

1. A radio frequency coil for a magnetic resonance imaging device, characterized in that the radio frequency coil has a first end and a second end in an axial direction, and the radio frequency coil comprises:
a first conductor portion at the first end, the first conductor portion comprising a first arc-shaped conductor and a second arc-shaped conductor opposed in a radial direction; and
a second conductor portion at the second end; the second conductor portion comprising a third arc-shaped conductor and a fourth arc-shaped conductor opposed in the radial direction;
wherein the first arc-shaped conductor and the third arc-shaped conductor are opposed in the axial direction, the second arc-shaped conductor and the fourth arc-shaped conductor are opposed in the axial direction, and
there are no rung conductors directly connected between the first conductor portion and the second conductor portion.

2. The radio frequency coil according to claim 1, wherein
the first arc-shaped conductor, the second arc-shaped conductor, the third arc-shaped conductor, and the fourth arc-shaped conductor are configured to operate simultaneously in a first excited state and a second excited state, wherein the first excited state and second excited state differ in phase by 90 degrees, in the first excited state, currents at both ends of each arc-shaped conductor are less than a current at the center, and in the second excited state, the current at the center of each arc-shaped conductor is less than the currents at both ends.

3. The radio frequency coil according to claim 2, wherein
both ends of each of the first arc-shaped conductor, the second arc-shaped conductor, the third arc-shaped conductor, and the fourth arc-shaped conductor are connected to different excitation sources, and
the different excitation sources are configured to apply currents in opposite directions to both ends of each of the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

4. The radio frequency coil according to claim 2, wherein
each of the first arc-shaped conductor, the second arc-shaped conductor, the third arc-shaped conductor, and the fourth arc-shaped conductor is configured in a resonant state,
only one end of each of the first arc-shaped conductor, the second arc-shaped conductor, the third arc-shaped conductor, and the fourth arc-shaped conductor is connected to a respective excitation source, and
the excitation source is configured to apply a current to the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

5. The radio frequency coil according to claim 2, wherein
a middle point of each of the first arc-shaped conductor, the second arc-shaped conductor, the third arc-shaped conductor, and the fourth arc-shaped conductor is connected to a respective balun, and
the baluns are configured to apply currents to the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the first excited state.

6. The radio frequency coil according to claim 2, wherein
both ends of each of the first arc-shaped conductor, the second arc-shaped conductor, the third arc-shaped conductor, and the fourth arc-shaped conductor are connected to different excitation sources, and
the different excitation sources are configured to apply currents in a same direction to both ends of each of the first arc-shaped conductor, the second arc-shaped conductor, the third arc-shaped conductor, and the fourth arc-shaped conductor, so that the first arc-shaped conductor, the second arc-shaped conductor, the third arc-shaped conductor, and the fourth arc-shaped conductor operate in the second excited state.

7. The radio frequency coil according to claim 1, wherein
the first conductor portion further comprises a fifth arc-shaped conductor and a sixth arc-shaped conductor opposed in the radial direction, the fifth arc-shaped conductor and the sixth arc-shaped conductor are respectively disposed on two sides between the first arc-shaped conductor and the second arc-shaped conductor, and the first arc-shaped conductor and the second arc-shaped conductor form a circular ring shape together with the fifth arc-shaped conductor and the sixth arc-shaped conductor, and
the second conductor portion further comprises a seventh arc-shaped conductor and an eighth arc-shaped conductor opposed in the radial direction, the seventh arc-shaped conductor and the eighth arc-shaped conductor are respectively disposed on two sides between the third arc-shaped conductor and the fourth arc-shaped conductor, and the third arc-shaped conductor and the fourth arc-shaped conductor form a circular ring shape together with the seventh arc-shaped conductor and the eighth arc-shaped conductor.

8. The radio frequency coil according to claim 7, wherein
the first to eighth arc-shaped conductors are configured to operate in a first excited state, wherein in the first excited state, currents at both ends of each arc-shaped conductor are less than a current at the center.

9. The radio frequency coil according to claim 8, wherein
both ends of each of the first to eighth arc-shaped conductors are connected to different excitation sources, and
the different excitation sources are configured to apply currents in opposite directions to both ends of each of the first to eighth arc-shaped conductors, so that the first to eighth arc-shaped conductors operate in the first excited state.

10. The radio frequency coil according to claim 8, wherein
each of the first to eighth arc-shaped conductors is configured in a resonant state,
only one end of each of the first to eighth arc-shaped conductors is connected to a respective excitation source, and
the excitation source is configured to apply a current to the first to eighth arc-shaped conductors, so that the first to eighth arc-shaped conductors operate in the first excited state.

11. The radio frequency coil according to claim 8, wherein
a middle point of each of the first to eighth arc-shaped conductors is connected to a respective balun, and
the baluns are configured to apply currents to the first to eighth arc-shaped conductors, so that the first to eighth arc-shaped conductors operate in the first excited state.

12. The radio frequency coil according to claim 12, wherein at least one of the first arc-shaped conductor, the second arc-shaped conductor, the third arc-shaped conductor, and the fourth arc-shaped conductor, and the fifth arc-shaped conductor, the sixth arc-shaped conductor, the seventh arc-shaped conductor, and the eighth arc-shaped conductor is connected to a resonant capacitor.

13. The radio frequency coil according to claim 8, wherein a radial outer side of at least one of the first arc-shaped conductor, the second arc-shaped conductor, the third arc-shaped conductor, and the fourth arc-shaped conductor, and the fifth arc-shaped conductor, the sixth arc-shaped conductor, the seventh arc-shaped conductor, and the eighth arc-shaped conductor is provided with a dielectric material.

14. A radio frequency coil for a magnetic resonance imaging device, characterized in that the radio frequency coil has a first end and a second end in an axial direction, and the radio frequency coil comprises:
a first conductor portion at the first end, the first conductor portion comprising a first arc-shaped conductor and a second arc-shaped conductor opposed in a radial direction;
a second conductor portion at the second end; the second conductor portion comprising a third arc-shaped conductor and a fourth arc-shaped conductor opposed in the radial direction;
wherein the first arc-shaped conductor and the third arc-shaped conductor are opposed in the axial direction, the second arc-shaped conductor and the fourth arc-shaped conductor are opposed in the axial direction, and
the radio frequency coil comprises two or more rung conductors spaced apart from the first to fourth arc-shaped conductors, a first rung conductor among the two or more rung conductors is disposed between the first arc-shaped conductor and the third arc-shaped conductor, and a second rung conductor among the two or more rung conductors is disposed between the second arc-shaped conductor and the fourth arc-shaped conductor.

15. The radio frequency coil according to claim 14, comprising:
the first to fourth arc-shaped conductors and the two or more rung conductors being configured to operate in a first excited state, wherein in the first excited state, currents at both ends of each of the arc-shaped conductors and rung conductors are less than a current at the center.

16. The radio frequency coil according to claim 15, wherein
both ends of each of the first to fourth arc-shaped conductors and the two or more rung conductors are connected to different excitation sources, and
the different excitation sources are configured to apply currents in opposite directions to the first to fourth arc-shaped conductors and the two or more rung conductors, so that the first to fourth arc-shaped conductors and the two or more rung conductors operate in the first excited state.

17. The radio frequency coil according to claim 15, wherein
each of the first to fourth arc-shaped conductors and the two or more rung conductors is configured in a resonant state,
only one end of each of the first to fourth arc-shaped conductors and the two or more rung conductors is connected to a respective excitation source, and
the excitation source is configured to apply a current to the first to fourth arc-shaped conductors and the two or more rung conductors, so that the first to fourth arc-shaped conductors and the two or more rung conductors operate in the first excited state.

18. The radio frequency coil according to claim 15, wherein
a middle point of each of the first to fourth arc-shaped conductors and the two or more rung conductors is connected to a respective balun, and
the baluns are configured to apply currents to the first to fourth arc-shaped conductors and the two or more rung conductors, so that the first to fourth arc-shaped conductors and the two or more rung conductors operate in the first excited state.

19. The radio frequency coil according to claim 14, wherein at least one of the first arc-shaped conductor, the second arc-shaped conductor, the third arc-shaped conductor, and the fourth arc-shaped conductor, and the two or more rung conductors is connected to a resonant capacitor.

20. The radio frequency coil according to claim 14, wherein a radial outer side of at least one of the first arc-shaped conductor, the second arc-shaped conductor, the third arc-shaped conductor, and the fourth arc-shaped conductor, and the two or more rung conductors is provided with a dielectric material.

21. A resonance assembly for a magnetic resonance imaging system, comprising:
the radio frequency coil according to claim 1;
a superconducting main coil configured to generate a polarized magnetic field; and
a magnetic gradient generator configured to generate a magnetic field gradient in the axial direction,
wherein the radio frequency coil is mounted in a coaxial relationship within the magnetic gradient generator.

22. The resonance assembly according to claim 21, wherein the magnetic gradient generator is cylindrical and the radio frequency coil is mounted within an inner wall of the magnetic gradient generator.
